(19) United States
(12) Patent Application Publication
(10) Pub. No.: US 2025/0241080 A1
(43) Pub. Date: Jul. 24, 2025

(54) SEMICONDUCTOR STRUCTURE INCLUDING CMOS IMAGE SENSORS AND LOGIC TRANSISTORS AND METHOD FOR MANUFACTURING THE SAME

(71) Applicant: TAIWAN SEMICONDUCTOR MANUFACTURING COMPANY, LTD., Hsinchu (TW)

(72) Inventors: Ching-Heng LIU, Hsinchu (TW); Yi-Hsuan FAN, Hsinchu (TW)

(73) Assignee: TAIWAN SEMICONDUCTOR MANUFACTURING COMPANY, LTD., Hsinchu (TW)

(21) Appl. No.: 18/421,222

(22) Filed: Jan. 24, 2024

(51) Int. Cl. H01L 27/146

(52) U.S. Cl. CPC H10F 39/8067; H10F 39/014; H10F 39/024; H10F 39/18; H10F 39/807

(57) ABSTRACT

A semiconductor structure includes: an epitaxial layer; photo-detecting portions disposed in the epitaxial layer and spaced apart from each other, each of the photo-detecting portions including a p-n junction; and trench isolations disposed in the epitaxial layer, each of the trench isolations being disposed to separate two adjacent ones of the photo-detecting portions from each other. Each of the trench isolations includes a first dielectric layer having a first refractive index and a first thickness, and a second dielectric layer having a second refractive index that is different from the first refractive index, and a second thickness that is different from the first thickness. The first dielectric layer and the second dielectric layer are arranged to prevent a light incident to one of the photo-detecting portions from entering an adjacent one of the photo-detecting portions.

### BACKGROUND

An image sensor is a sensor capable of converting incoming phonons into electrons. The two major types of digital image sensor are complementary metal-oxide-semiconductor (CMOS) image sensor and charge-coupled device (CCD) image sensor. The CCD image sensor may have a configuration similar to that of metal-oxide-semiconductor capacitors, and the CMOS image sensor may have a configuration similar to that of metal-oxide-semiconductor field-effect transistor amplifiers. Sometimes, the CMOS image sensor and the CCD image sensor may be used in different products. For example, consumer electronic products with camera functions generally utilize the CMOS image sensor as image sensors thereof owing to relatively low power consumption, small size, fast data processing, and low cost of the CMOS image sensor, whereas high-end broadcast video cameras generally utilize the CCD image sensor as image sensors thereof.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a schematic sectional view illustrating a semiconductor structure in accordance with some embodiments.

FIG. 2 is a schematic top view of a semiconductor structure in accordance with some other embodiments.

FIG. 3 is a flow diagram illustrating a method for manufacturing a semiconductor structure in accordance with some embodiments.

FIGS. 4 to 20 illustrate schematic views of intermediate stages of the method depicted in FIG. 3 in accordance with some embodiments.

### DETAILED DESCRIPTION

The following disclosure provides many different embodiments, or examples, for implementing different features of the disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “on,” “above,” “top,” “bottom,” “upper,” “lower,” “over,” “beneath,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

For the purposes of this specification and appended claims, unless otherwise indicated, all numbers expressing amounts, sizes, dimensions, proportions, shapes, formulations, parameters, percentages, quantities, characteristics, or other numerical values used in the specification and claims, are to be understood as being modified in all instances by the terms “about” and “substantially” even if the terms “about” and “substantially” are not explicitly recited with the values, amounts or ranges. Accordingly, unless indicated to the contrary, the numerical parameters set forth in the following specification and appended claims are not and need not be exact, but may be approximations and/or larger or smaller than specified as desired, may encompass tolerances, conversion factors, rounding off, measurement error, and other factors known to those of skill in the art depending on the desired properties sought to be obtained by the presently disclosed subject matter. For example, the terms “about” and “substantially,” when used with a value, can capture variations of, in some aspects±10%, in some aspects±5%, in some aspects±2.5%, in some aspects±1%, in some aspects±0.5%, and in some aspects±0.1% from the specified amount, as such variations are appropriate to perform the disclosed methods or employ the disclosed compositions.

The term “source/drain portion(s)” may refer to a source or a drain, individually or collectively dependent upon the context.

Quantum efficiency (QE) and dark current are indexes for determining the performance of a complementary metal-oxide-semiconductor (CMOS) image sensor. Quantum efficiency represents the number of electrons (or holes) that can be generated for each phonon detected by an image sensor. The larger the value of quantum efficiency is, the better the performance of the CMOS image sensor is. Dark current represents the number of electrons (or holes) flowing in an image sensor even in the absence of light, and the smaller the value of dark current is, the better the performance of the CMOS image sensor is. Sometimes, defects in the image sensor may result in the occurrence of dark current. For a semiconductor structure including a CMOS image sensor and a logic circuit formed on the same wafer, a trench isolation, which is commonly used in the logic circuit for electrically isolating two adjacent ones of logic transistors, may also be used in the CMOS image sensor for electrically isolating two adjacent ones of pixel units. The trench isolation used in the logic circuit is made of silicon oxide. In some embodiments, the silicon oxide used for making the trench isolation is substantially transparent to visible light, and thus a light incident to one of the pixel units may pass through the trench isolation and enter an adjacent one of the pixel units, thereby reducing the quantum efficiency of the one of the pixel units. Therefore, the present disclosure is directed to a semiconductor structure integrating a CMOS image sensor and a logic circuit, and the CMOS image sensor of the present disclosure has an improved quantum efficiency and a reduced dark current.

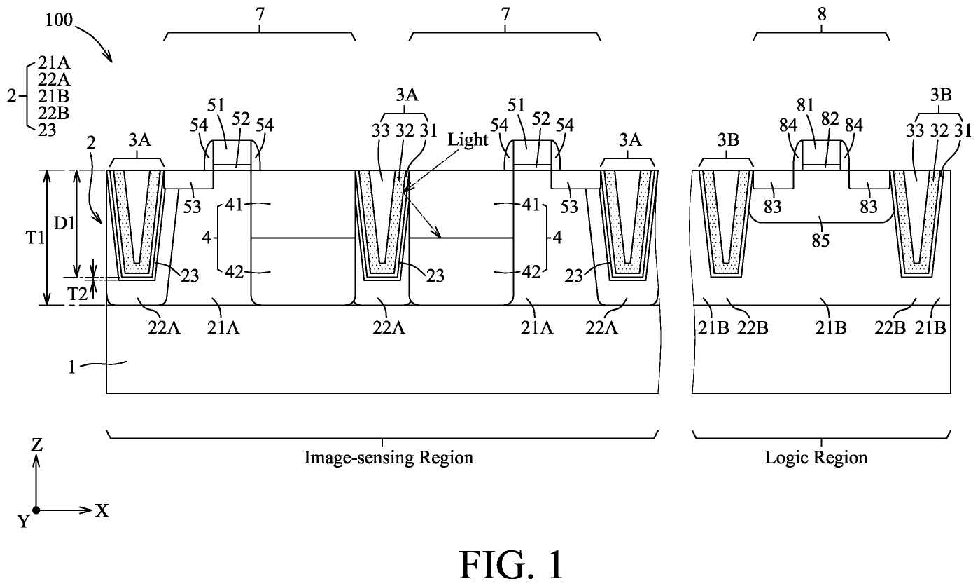

FIG. 1 is a schematic sectional view illustrating a semiconductor structure 100 in accordance with some embodiments. The semiconductor structure 100 includes multiple pixel units (e.g., two pixel units 7 exemplarily shown in FIG. 1) and multiple transistors (e.g., a transistor 8 exemplarily shown in FIG. 1) which are formed on the same substrate.

In some embodiments, the semiconductor structure 100 includes a substrate 1, a patterned epitaxial layer 2 disposed on the substrate 1, and multiple trench isolations 3A, 3B formed in the patterned epitaxial layer 2. In addition, photo-detecting portions 4 of the pixel units 7 are formed in the patterned epitaxial layer 2 and are spaced apart from each other. Each of the trench isolations 3A serves to separate two adjacent ones of the photo-detecting portions 4 from each other. In certain embodiments, source/drain portions 83 of the transistor 8 are also formed in the patterned epitaxial layer 2.

In some embodiments, the substrate 1 includes elemental semiconductor materials (such as crystalline silicon, diamond, or germanium), compound semiconductor materials (such as silicon carbide, gallium arsenide, indium arsenide, or indium phosphide), alloy semiconductor materials (such as silicon germanium, silicon germanium carbide, gallium arsenide phosphide, or gallium indium phosphide), or combinations thereof. In some embodiments, the substrate 1 may be a bulk semiconductor substrate, for example, but not limited to, a bulk substrate of silicon, germanium, silicon germanium, or other suitable semiconductor materials (such as the examples described earlier in the same paragraph). In some embodiments, the semiconductor material in the substrate 1 may be doped with n-type impurities to have an n-type conductivity, or may be doped p-type impurities to have a p-type conductivity. In some embodiments, the n-type impurities (or the p-type impurities) doped in the semiconductor material of the substrate 1 may be in a concentration ranging from about 1E17 atoms/cm³ to about 1E20 atoms/cm³. The n-type impurities may include group V elements, for example, but not limited to, nitrogen (N), phosphorous (P), arsenic (As), antimony (Sb), other suitable materials, or combinations thereof. The p-type impurities may include group III elements, for example, but not limited to, boron (B), aluminum (Al), gallium (Ga), indium (In), other suitable materials, or combinations thereof. In some other embodiments not shown herein, the substrate 1 may be configured as a semiconductor-on-insulator substrate which includes an underlying handle layer, a device layer for forming the pixel units 7 and the transistor 8 thereon, and a buried layer interposed between the underlying handle layer and the device layer. Each of the underlying handle layer and the device layer includes a semiconductor material such as the examples described earlier in the same paragraph. The buried layer may include an insulating material, for example, but not limited to, silicon oxide, silicon nitride, or silicon oxynitride. In such case, the device layer may be doped with n-type impurities to have an n-type conductivity, or may be doped p-type impurities to have a p-type conductivity. Other materials or configurations suitable for the substrate 1 are within the contemplated scope of the present disclosure. The substrate 1 includes an image-sensing region for forming the pixel units 7 thereon and a logic region for forming the transistor 8 thereon. The image-sensing region is displaced from the logic region.

The patterned epitaxial layer 2 is formed on the image-sensing region and the logic region of the substrate 1. The patterned epitaxial layer 2 includes a semiconductor material. Possible semiconductor materials suitable for forming the patterned epitaxial layer 2 are similar to those for forming the substrate 1, and thus the details thereof are omitted for the sake of brevity. Other semiconductor materials suitable for the patterned epitaxial layer 2 are within the contemplated scope of the present disclosure. The semiconductor material of the patterned epitaxial layer 2 may be the same or different from the semiconductor material in the substrate 1. In some embodiments, the patterned epitaxial layer 2 includes crystalline silicon. In some embodiments, the patterned epitaxial layer 2 has first epitaxial regions 21A, second epitaxial regions 21B, first underlying regions 22A, and second underlying regions 22B. As shown in FIG. 1, the first epitaxial regions 21A are disposed on the image-sensing region, and two adjacent ones of the first epitaxial regions 21A are spaced apart from each other by a corresponding one of the trench isolations 3A. The second epitaxial regions 21B are disposed on the logic region, and two adjacent ones of the second epitaxial regions 21B are spaced apart from each other by a corresponding one of the trench isolations 3B. The first underlying regions 22A are disposed on the image-sensing region, and each of the first underlying regions 22A is located beneath one of the trench isolations 3A to interconnect two adjacent ones of the first epitaxial regions 21A. The second underlying regions 22B are disposed on the logic region, and each of the second underlying regions 22B is located beneath one of the trench isolations 3B to interconnect two adjacent ones of the second epitaxial regions 21B. In some embodiments, each of the epitaxial regions 21A, 21B may have a thickness (T1) ranging from about 3000 Å to about 7000 Å.

The photo-detecting portions 4 are respectively formed in the first epitaxial regions 21A at the image-sensing region by an implantation process. Each of the photo-detecting portions 4 includes a first-type doped region 41 and a second-type doped region 42 which is disposed between the first-type doped region 41 and the substrate 1. In some embodiments, the first-type doped region 41 has a doping concentration ranging from about 1E10 atoms/cm³ to about 1E13 atoms/cm³. In some embodiments, the second-type doped region 42 has a doping concentration ranging from about 1E12 atoms/cm³ to about 1E14 atoms/cm³. The first-type doped region 41 has a conductivity type opposite to a conductivity type of the second-type doped region 42, so that the first-type doped region 41 and the second-type doped region 42 are in contact with each other to form a p-n junction for converting an incident light into electrical signals (e.g., current). That is, when the p-n junction is exposed to the incident light, electrons and holes may be created at a depletion region in the p-n junction. In some embodiments, when the substrate 1 is doped with p-type impurities to serve as a p-type substrate, the conductivity type of the first-type doped region 41 is p-type, and the conductivity type of the second-type doped region 42 is n-type. In some other embodiments, when the substrate 1 is doped with n-type impurities to serve as an n-type substrate, the conductivity type of the first-type doped region 41 is n-type, and the conductivity type of the second-type doped region 42 is p-type. In some other embodiments not shown herein, each of the photo-detecting portions 4 may further include an intrinsic (or un-doped) region (not shown) disposed between the first-type doped region 41 and the second-type doped region 42 to reduce the response time for converting an incident light into current. In some embodiments, as shown in FIG. 1, the second-type doped region 42 may be in contact with the substrate 1. In some other embodiments not shown herein, the second-type doped region 42 may be spaced apart from the substrate 1.

In some embodiments, each of the underlying regions 22A at the image-sensing region may be doped with n-type or p-type impurities to have a conductivity type that is opposite to the conductivity type of the second-type doped region 42. As such, at the image-sensing region, the photo-detecting portions 4 in two adjacent ones of the first epitaxial regions 21A are electrically isolated from each other through a corresponding one of the trench isolations 3A and a corresponding one of the first underlying regions 22A. In some embodiments, the n-type impurities (or the p-type impurities) in each of the first underlying regions 22A may be in a doping concentration ranging about 1E10 atoms/cm³ to about 1E13 atoms/cm³. It is worth noting that each of the trench isolations 3A at the image-sensing region is arranged to prevent a light incident to one of the photo-detecting portions 4 from entering an adjacent one of the photo-detecting portions 4. Since the trench isolations 3B at the logic region are formed together with the trench isolations 3A at the image-sensing region, the trench isolations 3B at the logic region has a configuration the same as that of the trench isolations 3A at the image-sensing region. In some embodiments, each of the trench isolations 3A, 3B may have a depth (D1) ranging from about 2000 Å to about 5000 Å. In some embodiments, each of the trench isolations 3A, 3B includes a first dielectric layer 31, a dielectric filling portion 33, and a second dielectric layer 32 sandwiched between the first dielectric layer 31 and the dielectric filling portion 33. In some embodiments, in each of the trench isolations 3A, the first dielectric layer 31 is formed to separate the second dielectric layer 32 from two adjacent ones of the first epitaxial regions 21A. In certain embodiments, in one of the trench isolations 3A (e.g., a middle one of the trench isolations 3A shown in FIG. 1), the first dielectric layer 31 is formed to separate the second dielectric layer 32 from two adjacent ones of the photo-detecting portions 4.

In order for each of the trench isolations 3A to serve as a light reflector, the first dielectric layer 31 has a first refractive index that is different from a second refractive index of the second dielectric layer 32. In some embodiments, the second refractive index is greater than the first refractive index. In some embodiments, the second refractive index is not less than about 1.3 times the first refractive index. The first refractive index and the second refractive index may be controlled by adjusting the atomic composition of the first dielectric layer 31 and the atomic composition of the second dielectric layer 32, respectively. In some embodiments, a nitrogen concentration of the second dielectric layer 32 is greater than a nitrogen concentration of the first dielectric layer 31. In addition, the transparency of each of the first and second dielectric layers 31, 32 may vary according to the nitrogen concentration thereof. Therefore, in some embodiments, the second dielectric layer 32, which has a relatively higher nitrogen concentration, has a transparency less than a transparency of the first dielectric layer 31. In other words, a transmittance of the second dielectric layer 32 is less than a transmittance of the first dielectric layer 31. As such, when a light in one of the photo-detecting portions 4 propagates toward an adjacent one of the photo-detecting portions 4, the light may be reflected by the second dielectric layer 32, and thus the light is prevented from entering into the adjacent photo-detecting portion 4. In some embodiments, by adjusting the nitrogen concentration, the first dielectric layer 31 may be formed to be transparent, and the second dielectric layer 32 may be formed to be opaque.

In some embodiments, the first dielectric layer 31 includes silicon oxide, and the second dielectric layer 32 includes silicon oxynitride. In some embodiments, each of the silicon oxide in the first dielectric layer 31 and the silicon oxynitride in the second dielectric layer 32 is amorphous. The silicon oxynitride in the second dielectric layer 32 may be designed to have a high enough nitrogen concentration so as to obtain a refractive index not less than about 1.3 times the refractive index of the silicon oxide in the first dielectric layer 31. The second dielectric layer 32 may have a thickness that is greater than a thickness of the first dielectric layer 31 to achieve a desirable quantum efficiency. In some embodiments, the thickness of the second dielectric layer 32 may be not less than about 3.5 times the thickness of the first dielectric layer 31. The first dielectric layer 31, which may be relatively transparent due to the absence of nitrogen, is mainly used to release stress caused by lattice mismatch between the second dielectric layer 32 (e.g., silicon oxynitride) and the patterned epitaxial layer 2 (e.g., silicon). In some embodiments, the first dielectric layer 31 has a thickness greater than about 50 Å. In the case that the thickness of the first dielectric layer 31 is not greater than about 50 Å, the second dielectric layer 32 may be easily peeled off from the first dielectric layer 31. In some embodiments, the dielectric filling portion 33 includes silicon oxide. The presence of the dielectric filling portion 33 is for reducing unexpected adverse impact on the device performance of the transistor 8 on the logic region when the trench isolations 3B of the present disclosure are used for isolation.

In some embodiments, the substrate 1 has a p-type conductivity, the first-type doped region 41 has a p-type conductivity, the second-type doped region 42 has an n-type conductivity, and the peripheral doped region 23 has a p-type conductivity.

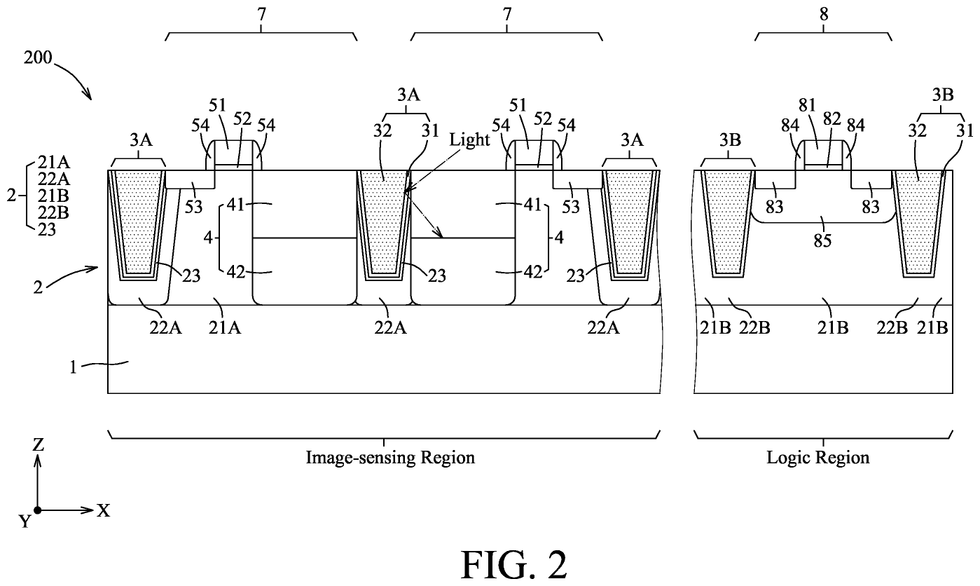

FIG. 2 is a schematic sectional view illustrating a semiconductor structure 200 in accordance with some other embodiments. The semiconductor structure 200 has a structure similar to that of the semiconductor structure 100, but the dielectric filling portion 33 shown in FIG. 1 is omitted. The volume ratio of the second dielectric layer 32 in each of the trench isolations 3A in the semiconductor structure 200 is greater than that in the semiconductor structure 100. Therefore, each of the photo-detecting portions 7 in the semiconductor structure 200 may have a better quantum efficiency than each of the photo-detecting portions 7 in the semiconductor structure 100.

In some embodiments, the patterned epitaxial layer 2 further includes multiple peripheral doped regions 23 which are respectively formed around the isolation trenches 3A on the image-sensing region by an implantation process. In some embodiments, each of the peripheral doped regions 23 is formed to improve electrical isolation between the photo-detecting portions 4 in two adjacent ones of the first epitaxial regions 21A. Thus, the peripheral doped regions 23 may be doped with n-type impurities or p-type impurities to have a conductivity type the same as the conductivity type of the first underlying regions 22A. In some embodiments, the n-type impurities (or the p-type impurities) in each of the peripheral doped regions 23 may be in a doping concentration ranging about 1E12 atoms/cm³ to about 1E14 atoms/cm³. In some embodiments, each of the peripheral doped regions 23 has a thickness (T2) less than about 1000 Å.

In some embodiment, the semiconductor structure 100 further includes multiple transfer gates 51, multiple transfer gate dielectrics 52, and multiple floating diffusion portions 53 at the image-sensing region.

The transfer gates 51 are respectively formed on the first epitaxial regions 21A. In some embodiments, each of the transfer gates 51 includes polycrystalline silicon. Each of the transfer gate dielectrics 52 is disposed to separate one of the transfer gates 51 from a corresponding one of the first epitaxial regions 21A. In some embodiments, each of the transfer gate dielectrics 52 includes silicon oxide. The floating diffusion portions 53 are respectively formed in the first epitaxial regions 21A, such that each of the photo-detecting portions 4 and a corresponding one of the floating diffusion portions 53 are respectively located at two opposite sides of a corresponding one of the transfer gates 51. Each of the floating diffusion portions 53 is doped with n-type impurities or p-type impurities such that the floating diffusion portions 53 have a conductivity type that is the same as the conductivity type of the second-type region 42 of each of the photo-detecting portions 4. In some embodiments, the n-type impurities (or the p-type impurities) in each of the floating diffusion portions 53 may be in a doping concentration ranging about 1E12 atoms/cm³ to about 1E15 atoms/cm³. Each of the pixel units 7 includes one of the photo-detecting portions 4, a corresponding one of the floating diffusion portions 53, a corresponding one of the transfer gates 51, and a corresponding one of the transfer gate dielectrics 52. In the case that in one of the photo-detecting portions 4, the first-type doped region 41 is p-type and the second-type doped region 42 is n-type, electrons and holes generated after absorption of an incident light may respectively accumulate at the second-type doped region 42 (i.e., n-type region) and the first-type doped region 41 (i.e., p-type region). When a positive voltage is applied to the corresponding transfer gate 51, the electrons accumulated at the second-type doped region 42 (i.e., n-type region) of the abovementioned photo-detecting portion 4 are permitted to flow to the corresponding floating diffusion portion 53 (i.e., n-type region) through a channel between the second-type doped region 42 (i.e., n-type region) of the abovementioned photo-detecting portion 4 and the corresponding floating diffusion portion 53 (i.e., n-type region), so that the electrons can be stored at the corresponding floating diffusion portion 53 (i.e., n-type region). In some embodiments, the corresponding floating diffusion portion 53 may be further connected to other circuits for electrical signal processing.

In some embodiments, the semiconductor structure 100 further includes multiple pairs of transfer gate spacers 54. Each pair of the transfer gate spacers 54 are respectively dispose at two opposite sides of a corresponding one of the transfer gates 51. In some embodiments, each of the transfer gate spacers 54 may be made of a dielectric material which includes a nitride-based material, such as silicon nitride, silicon oxynitride, silicon carbon nitride, silicon oxycarbonnitride, but is not limited thereto. Other dielectric materials suitable for the transfer gate spacers 54 are within the contemplated scope of the present disclosure.

In some embodiment, the semiconductor structure 100 further includes a logic gates 81, a logic gate dielectric 82, and two source/drain portions 83 at the logic region. The transistor 8 includes the logic gate 81, the logic gate dielectric 82 and the two source/drain portions 83.

As shown in FIG. 1, the logic gate 81 is formed on a middle one of the second epitaxial regions 21B. In some embodiments, the logic gate 81 includes polycrystalline silicon. The logic gate dielectric 82 is disposed to separate the logic gate 81 from the middle second epitaxial region 21B. In some embodiments, the logic gate dielectric 82 includes silicon oxide. The two source/drain portions 83 are formed in the middle second epitaxial region 21B, and are respectively located at two opposite sides of the logic gate 81. In some embodiments, when the transistor 8 is an n-FET, the two source/drain portions 83 are doped with n-type impurities. In some other embodiments, when the transistor 8 is a p-FET, the two source/drain portions 83 are doped with p-type impurities. In some embodiments, the transistor 8 further includes two logic gate spacers 84 which are respectively dispose at two opposite sides the logic gate 81. Possible materials suitable for forming the logic gate spacers 84 are similar to those for the transfer gate spacers 54, and thus the details thereof are omitted for the sake of brevity. In some embodiments, the transistor 8 further includes a well portion 85 which is formed in the middle second epitaxial region 21B by an implantation process, so as to avoid a leakage current between the substrate 1 and one of the source/drain portions 83. The well portion 85 has a depth deeper than a depth of the source/drain portions 83, and has a conductivity type that is opposite to the conductivity type of the source/drain portions 83.

In some alternative embodiments, the semiconductor structure 100, 200 may further include additional features, and/or some features present in the semiconductor structure 100 may be modified, replaced, or eliminated without departure from the spirit and scope of the present disclosure. For example, the semiconductor structure 100, 200 may further include an interconnect structure (not shown) formed on the pixel units 7 and the transistor 8 so as to permit each of the pixel units 7 and the transistor 8 to be controlled by an external circuit. In some embodiments, the interconnect structure may include a plurality of interconnect layers each including an inter-layer dielectric (ILD) portion (or an inter-metal dielectric (IMD) portion) in which a plurality of electrically conductive elements (for example, metal contacts, metal lines and/or metal vias) are formed so as to permit each of the pixel units 7 and the transistor 8 to be electrically connected to the external circuit through the electrically conductive elements.

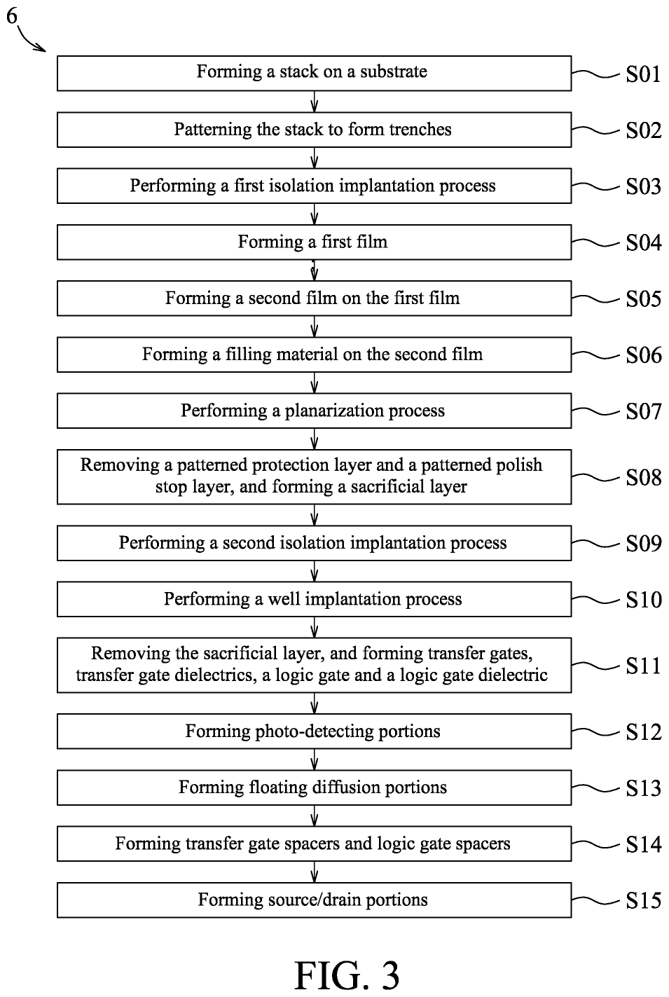

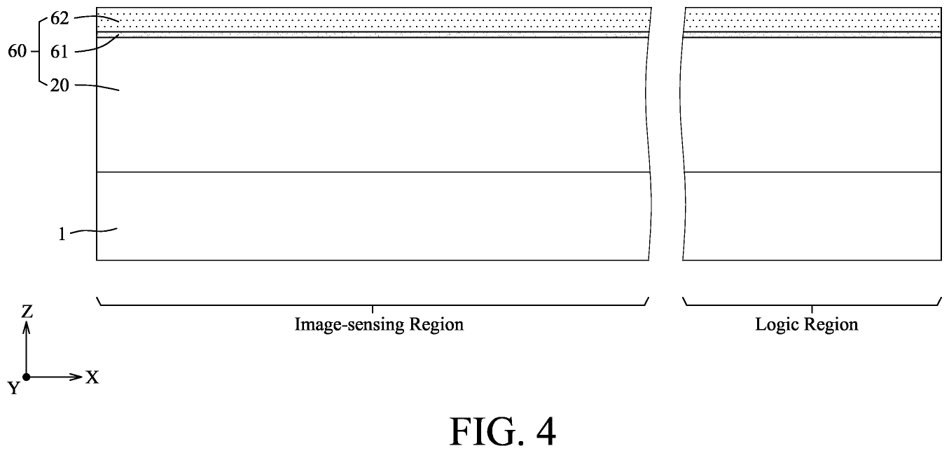

FIG. 3 is a flow diagram illustrating a method 6 for manufacturing a semiconductor structure (for example, but not limited to, the semiconductor structure 100 including the pixel units 7 and the transistor 8 as shown in FIG. 1) in accordance with some embodiments. The method 6 may include steps S01 to S15. FIGS. 4 to 20 illustrate schematic views of intermediate stages of the method 7 in accordance with some embodiments. Similar numerals from the above-mentioned embodiments have been used where appropriate, with some construction differences being indicated with different numerals. It should be noted that each of the number of the pixel units 7 and the number of the transistor 8 may vary according to practical requirements.

Referring to FIG. 3 and the example illustrated in FIG. 4, the method 6 begins at step S01, where a stack 60 is formed on the image-sensing region and the logic region of the substrate 1. In some embodiments, the stack 60 includes an epitaxial layer 20, a protection layer 61 and a polish stop layer 62 sequentially formed on the substrate 1.

In some embodiments, the semiconductor material in the substrate 1 may be pre-doped with n-type impurities to have an n-type conductivity, or may be doped p-type impurities to have a p-type conductivity. In some embodiments, the n-type impurities (or the p-type impurities) doped in the semiconductor material of the substrate 1 may be in a concentration ranging from about 1E17 atoms/cm³ to about 1E20 atoms/cm³.

The epitaxial layer 20 will be formed into the patterned epitaxial layer 2 as described above with reference to FIG. 1 in a subsequent step, and thus the epitaxial layer 20 includes the semiconductor material of the patterned epitaxial layer 2. In some embodiments, the epitaxial layer 20 is made of crystalline silicon. In some embodiments, the epitaxial layer 20 has a thickness ranging from about 3000 Å to about 7000 Å. In some embodiments, the epitaxial layer 20 may be doped with n-type impurities or p-type impurities to have a conductivity type that is the same as the conductivity type of the substrate 1. In some other embodiments, the epitaxial layer 20 may be un-doped. For example, the substrate 1 includes silicon which is doped with p-type impurities, and the epitaxial layer 20 includes silicon which is un-doped. It is noted that, although the epitaxial layer 20 is un-doped, a portion of the p-type impurities originally doped in the substrate 1 may diffuse into the epitaxial layer 20. As such, the portion of the p-type impurities in the epitaxial layer 20 may have a concentration that gradually decreases from an interface between the substrate 1 and the epitaxial layer 20 to an upper surface of the epitaxial layer 20 opposite to the substrate 1.

The protection layer 61 serves to protect the upper surface of the epitaxial layer 20 from being contaminated or oxidized. In some embodiments, the protection layer 61 includes an oxide such as silicon oxide. Other suitable dielectric materials suitable for forming the protection layer 61 are within the contemplated scope of the present disclosure. In some embodiments, the protection layer 61 has a thickness ranging from about 50 Å to about 300 Å. In some embodiments, the polish stop layer 62 includes silicon nitride. In some embodiments, the polish stop layer 62 has a thickness ranging from about 500 Å to about 2000 Å.

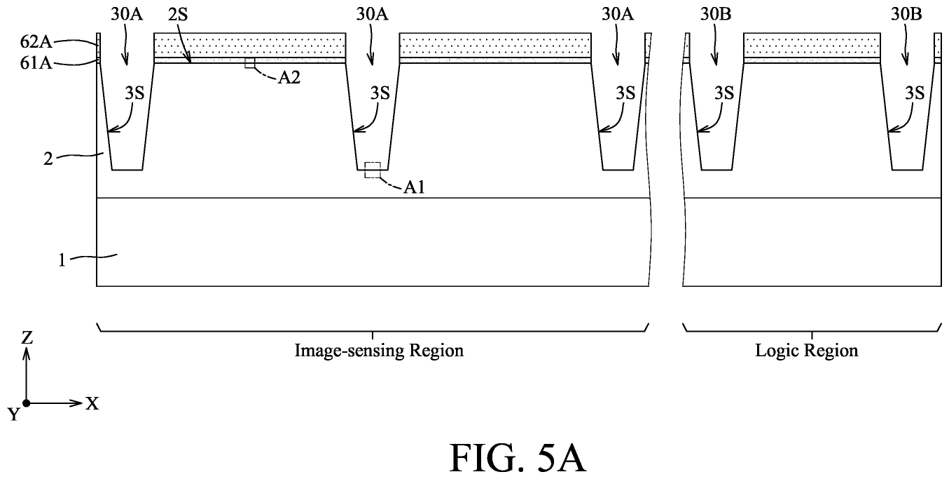

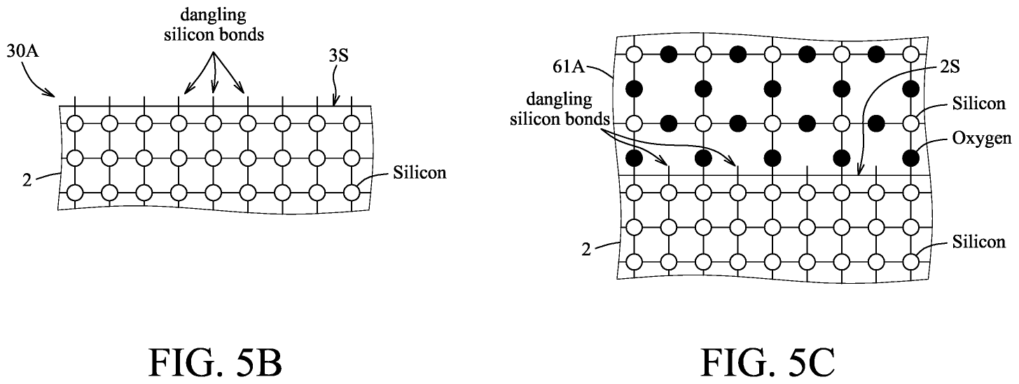

Referring to FIG. 3 and the example illustrated in FIG. 5A, the method 6 proceeds to step S02, where the stack 60 (see FIG. 4) is patterned to form first trenches 30A on the image-sensing region and second trenches 30B on the logic region. FIG. 5A is a schematic sectional view similar to FIG. 4, but illustrating the structure after step S02. After step S02, the epitaxial layer 20, the protection layer 61 and the polish stop layer 62 in the stack 60 (see FIG. 4) are respectively formed into the patterned epitaxial layer 2, a patterned protection layer 61A and a patterned polish stop layer 62A. Each of the trenches 30A, 30B includes an inner surface 3S. FIG. 5B is a partially enlarged view of area A1 in FIG. 5A in accordance with some embodiments. In some embodiments, during step S02, dangling silicon bonds may be formed at the inner surface 3S of each of the trenches 30A, 30B. FIG. 5C is a partially enlarged view of area A2 in FIG. 5A in accordance with some embodiments. In some embodiments, since the upper surface of the epitaxial layer 20 (see FIG. 4) may be imperfect and may have defects before forming the protection layer 61 (see FIG. 4) thereon, although the patterned protection layer 61A is formed on an upper surface 2S of the patterned epitaxial layer 20, the upper surface 2S of the patterned epitaxial layer 2 may have dangling silicon bonds formed thereon.

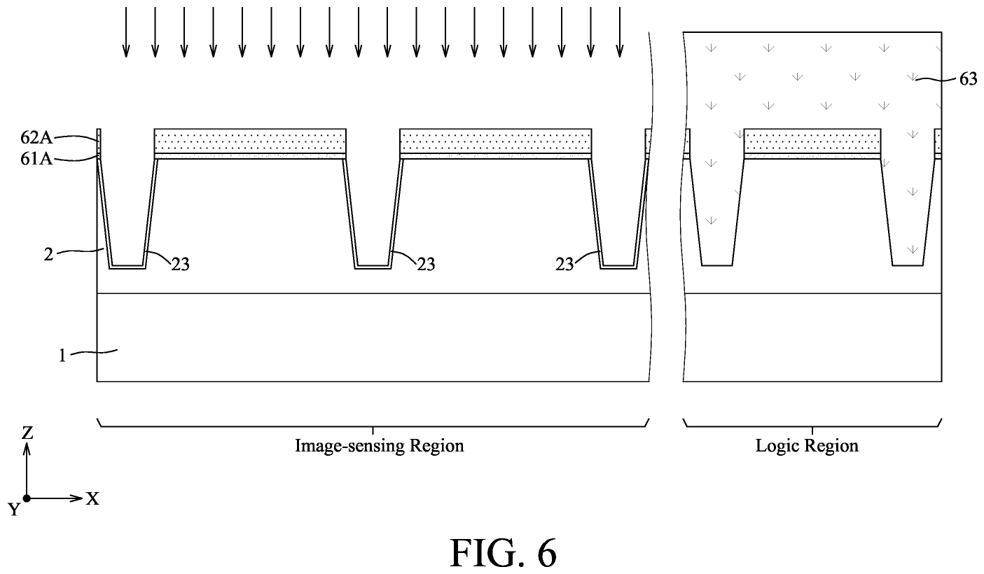

Referring to FIG. 3 and the example illustrated in FIG. 6, the method 6 proceeds to step S03, where the peripheral doped regions 23 are formed in the patterned epitaxial layer 2 respectively through the trenches 30A on the image-sensing region by a first isolation implantation process. FIG. 6 is a schematic sectional view similar to FIG. 5A, but illustrating the structure after step S03. In order to electrical isolate two adjacent ones of the pixel units 7 (see FIG. 1), n-type impurities or p-type impurities are doped in the peripheral doped regions 23 such that the peripheral doped regions 23 have a conductivity type that is the same as the conductivity type of the substrate 1. In some embodiments, the n-type impurities (or the p-type impurities) in each of the peripheral doped regions 23 may be in a doping concentration ranging about 1E12 atoms/cm³ to about 1E14 atoms/cm³.

In some embodiments, the first isolation implantation process includes (i) forming a patterned photoresist layer 63 (see FIG. 6) on the structure shown in FIG. 5A by, for example, but not limited to, a spin coating, followed by an exposure process and a development process to expose a portion of the patterned epitaxial layer 2 at the image-sensing region, (ii) implanting the n-type impurities (or the p-type impurities) into the exposed portion of the patterned epitaxial layer 2, and (iii) removing the patterned photoresist layer 63 by, for example, but not limited to, an ashing process and/or a photoresist stripping process.

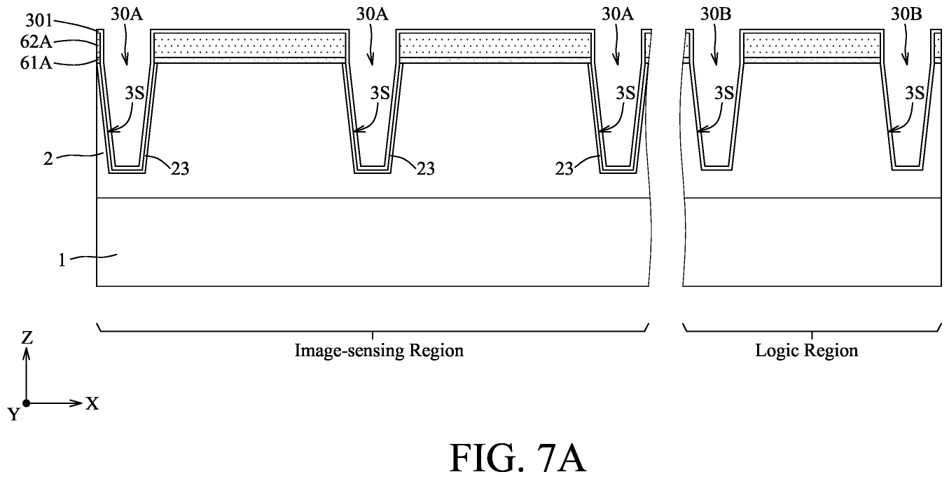

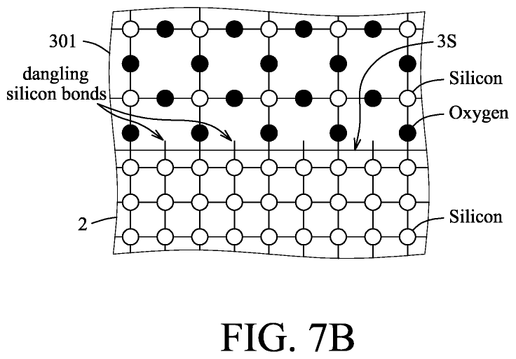

Referring to FIG. 3 and the example illustrated in FIG. 7A, the method 6 proceeds to step S04, where a first film 301 is formed on the structure obtained after step S03. FIG. 7A is a schematic sectional view similar to FIG. 6, but illustrating the structure after step S04.

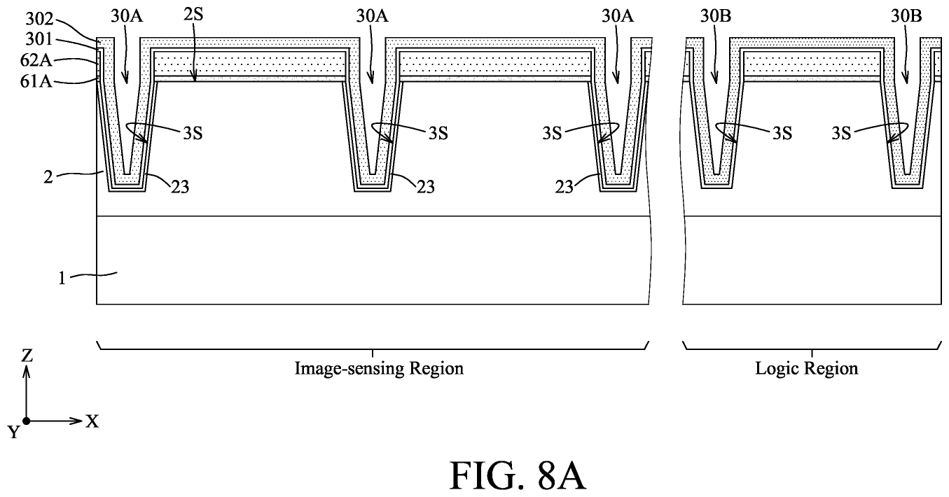

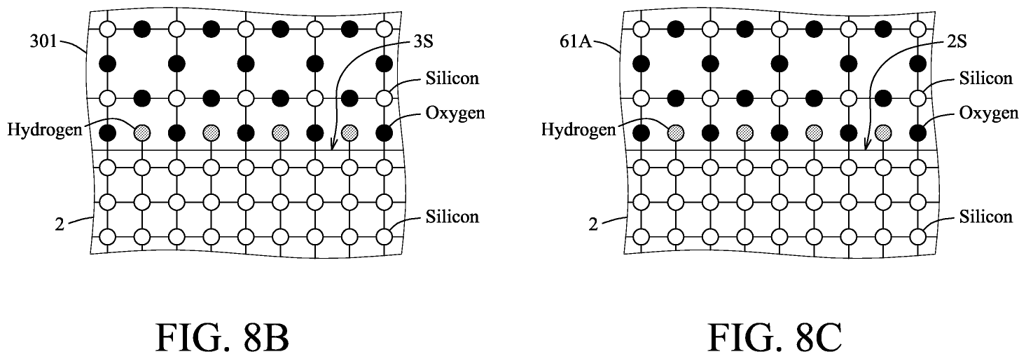

In some embodiments, the first film 301 is formed on the patterned polish stop layer 62A and the patterned protection layer 61A, and extends to cover the inner surface 3S of each of the trenches 30A, 30B. In some embodiments, the first film 301 is formed by furnace oxidation, chemical vapor deposition (CVD), or other suitable deposition techniques. The first film 301 is used for forming the first dielectric layer 31 of each of the trench isolations 3A, 3B (see FIG. 1 or FIG. 2), and thus the first film 301 includes the material of the first dielectric layer 31. In certain embodiments, the first film 301 includes silicon oxide. In some embodiments, the first film 301 has a thickness greater than about 50 Å. In the case that the thickness of the first film 301 is not greater than about 50 Å, a second film 302 (to be sequentially formed, see FIG. 8A) may be easily peeled off from the first film 301. FIG. 7B is a schematic view similar to FIG. 5B, but illustrating the structure after step S04. For each of the trenches 30A, 30B, although the first film 301 is formed on the inner surface 3S thereof, the inner surface 3S still has dangling silicon bonds remaining thereon.

Referring to FIG. 3 and the example illustrated in FIG. 8A, the method 6 proceeds to step S05, where a second film 302 is formed on the first film 301. FIG. 8A is a schematic sectional view similar to FIG. 7A, but illustrating the structure after step S05.

In some embodiments, the second film 302 is formed by furnace oxidation, CVD, or other suitable deposition techniques. The second film 302 is used for forming the second dielectric layer 32 of each of the trench isolations 3A, 3B (see FIG. 1), and thus the second film 302 includes the material of the second dielectric layer 32. In certain embodiments, the second film 302 includes silicon oxynitride.

In some embodiments, a precursor gas mixture for forming the second film 302 includes silicon-containing gas (e.g., silane), oxygen-containing gas (e.g., oxygen gas and/or water vapor) and nitrogen-containing gas (e.g., ammonia). During formation of the second film 302, hydrogen atoms, which are produced due to a reaction of the precursor gas mixture, are permitted to access to and react with the dangling silicon bonds on the upper surface 2S of the patterned epitaxial layer 2 and the inner surface 3S of each of the trenches 30A, 30B due to small size of the hydrogen atoms. FIG. 8B is a schematic view similar to FIG. 7B, but illustrating the structure after step S05. FIG. 8C is a schematic view similar to FIG. 5C, but illustrating the structure after step S05. As shown in FIGS. 8B and 8C, after formation of the second film 302, the hydrogen atoms are respectively bonded to silicon atoms having the dangling silicon bonds (see also FIGS. 7B and 5C), and thus a number of the dangling silicon bonds formed on the upper surface 2S of the patterned epitaxial layer 2 and the inner surface 3S of each of the trenches 30A, 30B can be greatly reduced.

Furthermore, a flow rate of each of the silicon-containing gas (e.g., silane), the oxygen-containing gas (e.g., oxygen gas and/or water vapor) and the nitrogen-containing gas (e.g., ammonia) in the precursor gas mixture for forming the second film 302 may be adjusted so as to permit the silicon oxynitride of the second film 302 to have a refractive index that is not less than about 1.3 times a refractive index of the silicon oxide of the first film 301. In some embodiments, the second film 302 has a thickness that is not less than about 3.5 time a thickness of the first film 301. In the case that the refractive index of the second film 302 is less than about 1.3 time the refractive index of the first film 301, or in the case that the thickness of the second film 302 is less than about 3.5 times of the thickness of the first film 301, each of the trench isolations 3A to be formed subsequently may have insufficient light reflection capability, thereby reducing the quantum efficiency.

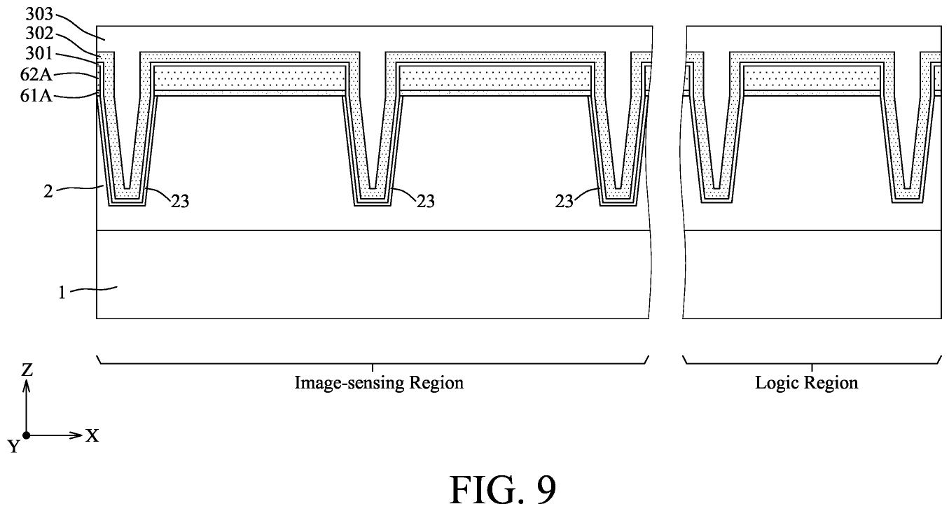

Referring to FIG. 3 and the example illustrated in FIG. 9, the method 6 proceeds to step S06, where a filling material 303 is formed on the second film 302 to fill the trenches 30A, 30B (see FIG. 8A). FIG. 9 is a schematic sectional view similar to FIG. 8A, but illustrating the structure after step S06.

In some embodiments, the filling material 303 is formed by furnace oxidation, CVD, or other suitable deposition techniques. The filling material 303 is used for forming the dielectric filling portion 33 of each of the trench isolations 3A, 3B (see FIG. 1), and thus the filling material 303 includes the material of the dielectric filling portion 33. In certain embodiments, the filling material 303 includes silicon oxide.

Referring to FIG. 3 and the example illustrated in FIG. 10, the method 6 proceeds to step S07, where a planarization process is performed to expose the patterned polish stop layer 62A. FIG. 10 is a schematic sectional view similar to FIG. 9, but illustrating the structure after step S07.

During the planarization process, excess portions of the first film 301, the second film 302 and the filling material 303 above the patterned polish stop layer 62A are removed, and thus a stack of the first film 301, the second film 302 and the filling material 303 is patterned into preformed isolation trenches 9A at the image-sensing region and preformed isolation trenches 9B at the logic region. Each of the preformed isolation trenches 9A, 9B includes a portion of the patterned first film 301′, a portion of the patterned second film 302′ and a portion of the patterned filling material 303′.

The patterned epitaxial layer 2 has the first epitaxial regions 21A and the first underlying regions 22A on the image-sensing region, and the second epitaxial regions 21B and the second underlying regions 22B on the logic region, as described above with reference to FIG. 1. As shown in FIG. 10, two adjacent ones of the first epitaxial regions 21A are spaced apart from each other by a corresponding one of the preformed trench isolations 9A, and two adjacent ones of the second epitaxial regions 21B are spaced apart from each other by a corresponding one of the preformed trench isolations 9B. Each of the first underlying regions 22A is located beneath one of the preformed trench isolations 9A to interconnect two adjacent ones of the first epitaxial regions 21A, and each of the second underlying regions 22B is located beneath one of the preformed trench isolations 9B to interconnect two adjacent ones of the second epitaxial regions 21B.

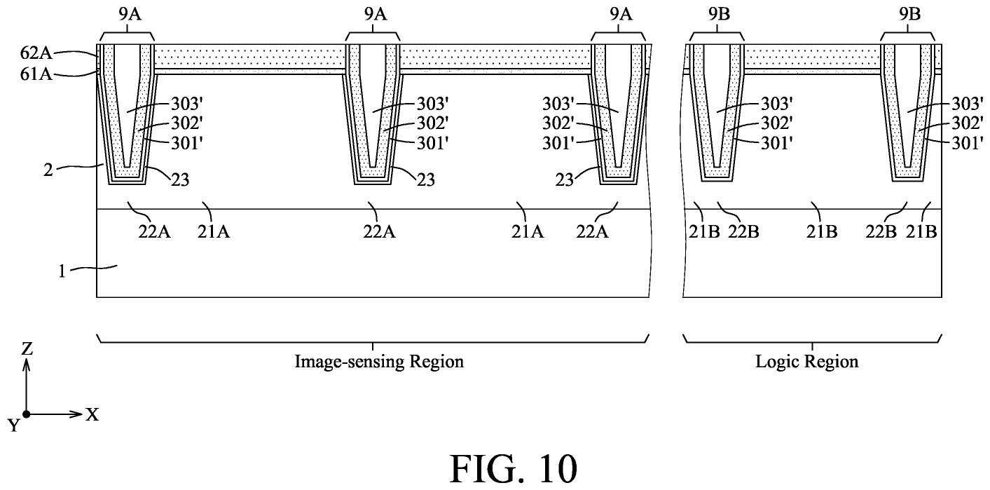

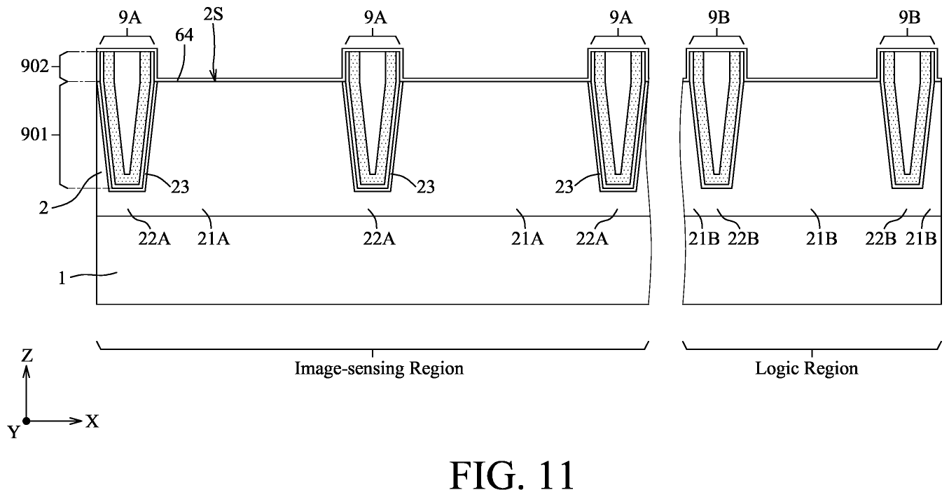

Referring to FIG. 3 and the example illustrated in FIG. 11, the method 6 proceeds to step S08, where the patterned polish stop layer 62A and the patterned protection layer 61A (see FIG. 10) are removed by an etching process such as dry etching and/or wet etching, and then a sacrificial layer 64 is formed on the patterned epitaxial layer 2 by furnace oxidation, chemical vapor deposition (CVD), or other suitable deposition techniques. FIG. 11 is a schematic sectional view similar to FIG. 10, but illustrating the structure after step S08.

After removing the patterned polish stop layer 62A and the patterned protection layer 61A, each of the preformed trench isolations 9A, 9B has a lower portion 901 that is formed in the patterned epitaxial layer 2 and an upper portion 902 that is disposed on the lower portion 901 opposite to the substrate 1 and that is located at a level higher than a level of the upper surface 2S of the patterned epitaxial layer 2.

The sacrificial layer 64 serves to protect the upper surface 2S of the patterned epitaxial layer 2 from being contaminated or oxidized. In some embodiments, the sacrificial layer 64 may include silicon oxide. In some embodiments, the sacrificial layer 64 may be formed to further cover the preformed trench isolations 9A, 9B according to the deposition techniques used.

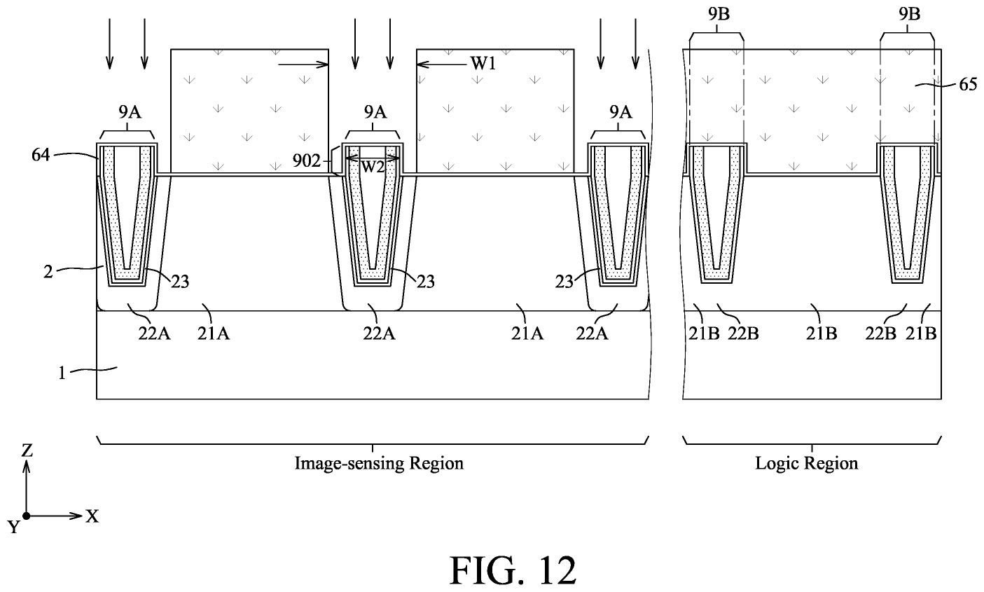

Referring to FIG. 3 and the example illustrated in FIG. 12, the method 6 proceeds to step S09, where a second isolation implantation process is performed such that each of the underlying regions 22A at the image-sensing region may be doped with n-type or p-type impurities to have a conductivity type that is the same as the conductivity type of the peripheral doped regions 23 for electrical isolation between two adjacent ones of the pixel units 7 (see FIG. 1). FIG. 12 is a schematic sectional view similar to FIG. 11, but illustrating the structure after step S09.

In some embodiments, the n-type impurities (or the p-type impurities) in each of the first underlying regions 22A may be in a doping concentration ranging about 1E10 atoms/cm³ to about 1E13 atoms/cm³.

In some embodiments, the second isolation implantation process may be performed in a manner similar to the first isolation implantation process in step S03, but process parameters (e.g., energy, dosage of impurities, species of impurities, etc.) of the second isolation implantation process are adjusted so that the n-type impurities or p-type impurities may reach a desired depth and the first underlying regions 22A may have a desired doping concentration. In some embodiments, a patterned photoresist layer 65 used in the second isolation implantation process is formed to expose portions of the patterned epitaxial layer 2 respectively in position corresponding to the preformed trench isolations 9A at the image-sensing region. In some embodiments, the dimension (W1) of each of the expose portions of the patterned epitaxial layer 2 may be slightly greater than the dimension (W2) of the upper portion 902 of a corresponding one of the preformed trench isolations 9A.

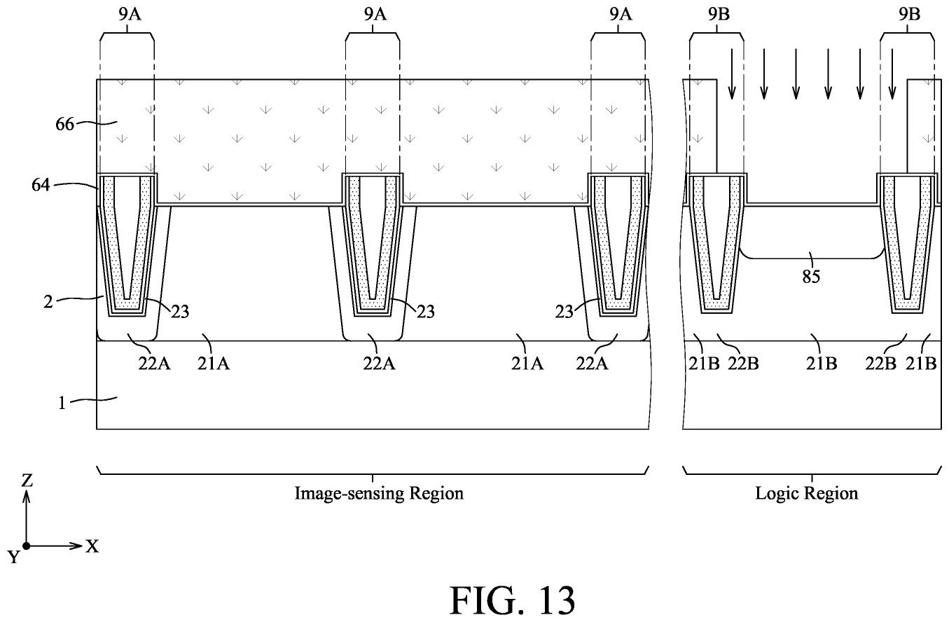

Referring to FIG. 3 and the example illustrated in FIG. 13, the method 6 proceeds to step S10, where the well portion 85 of the transistor 8 (see FIG. 1) is formed in the middle second epitaxial region 21B by a well implantation process. FIG. 13 is a schematic sectional view similar to FIG. 12, but illustrating the structure after step S10.

In some embodiments, the well implantation process may be performed in a manner similar to the second isolation implantation process in step S09, but process parameters (e.g., energy, dosage of impurities, species of impurities, etc.) of the well implantation process are adjusted so that the well portion 85 may be formed at a desired depth and may have a desired doping concentration. In some embodiments, a patterned photoresist layer 66 used in the well implantation process is formed to expose the middle second epitaxial region 21B at the logic region.

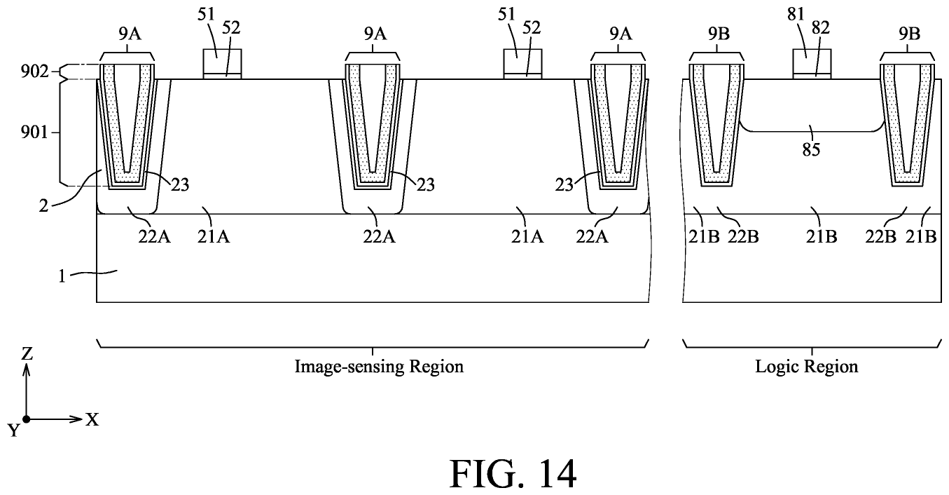

Referring to FIG. 3 and the example illustrated in FIG. 14, the method 6 proceeds to step S11, where the sacrificial layer 64 (see FIG. 13) is removed, and then the transfer gates 51 and the transfer gate dielectrics 52 of the pixel units 7 (see also FIG. 1), and the logic gate 81 and the logic gate dielectric 82 of the transistor 8 (see also FIG. 1) are formed. FIG. 14 is a schematic sectional view similar to FIG. 13, but illustrating the structure after step S11.

In some embodiments, the sacrificial layer 64 is removed by an etching process such as dry etching and/or wet etching. In some embodiments, formation of the elements 51, 52, 81, 82 may include (i) forming a gate dielectric layer (not shown) for forming the transfer gate dielectrics 52 of the pixel units 7 and the logic gate dielectric 82 of the transistor 8 on the patterned epitaxial layer 2 at the image-sensing region and the logic region by furnace oxidation, chemical vapor deposition (CVD), or other suitable deposition techniques, (ii) forming a gate electrode layer (not shown) for forming the transfer gates 51 of the pixel units 7 and the logic gate 81 of the transistor 8 on the gate dielectric layer, and (iii) patterning the gate electrode layer and the gate dielectric layer by a patterning process including lithography and etching processes. Accordingly, the gate dielectric layer is patterned into the transfer gate dielectrics 52 respectively formed on the first epitaxial regions 21A at the image sensing region, and the logic gate dielectric 82 formed on the middle second epitaxial region 21B at the logic region. The gate electrode layer is patterned into the transfer gates 51 respectively formed on the transfer gate dielectrics 52, and the logic gate 81 formed on the logic gate dielectric 82.

In some embodiments, after step S11, the height (in the Z direction) of the upper portion 902 of each of the preformed trench isolations 9A, 9B (see FIG. 14) may be reduced due to the etching processes in step S11, as compared to the upper portion 902 of each of the preformed trench isolations 9A, 9B obtained after step S08 (see FIG. 11).

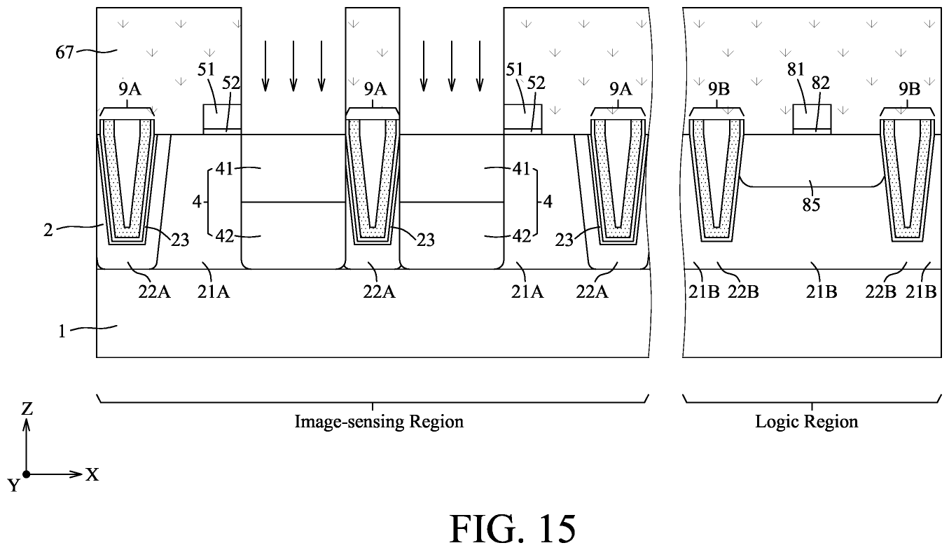

Referring to FIG. 3 and the example illustrated in FIG. 15, the method 6 proceeds to step S12, where the photo-detecting portions 4 are respectively formed in the first epitaxial regions 21A, and each of the photo-detecting portions 4 is located at one side of a corresponding one of the transfer gates 51. FIG. 15 is a schematic sectional view similar to FIG. 14, but illustrating the structure after step S12.

In some embodiments, formation of the photo-detecting portions 4 includes (i) forming the first-type doped region 41 by a first implantation process, and (ii) forming the second-type doped region 42 by a second implantation process. Each of the first and second implantation process in step S12 may be performed in a manner similar to the second isolation implantation process in step S09, but process parameters (e.g., energy, dosage of impurities, species of impurities, etc.) of each of the first and second implantation processes are adjusted so that the first-type doped region 41 (or the second-type doped region 42) may be formed at a desired depth and may have a desired doping concentration. In step S12, the first implantation process may be performed before or after the second implantation process. In some embodiments, a patterned photoresist layer 67 used in the first and second implantation processes in step S12 is formed to expose predetermined portions of the patterned epitaxial layer 2 that are respectively designed for forming the photo-detecting portions 4 therein. In some embodiments, at the image-sensing region, upper surfaces of the transfer gates 51 and the preformed trench isolations 9A are covered by the patterned photoresist layer 67.

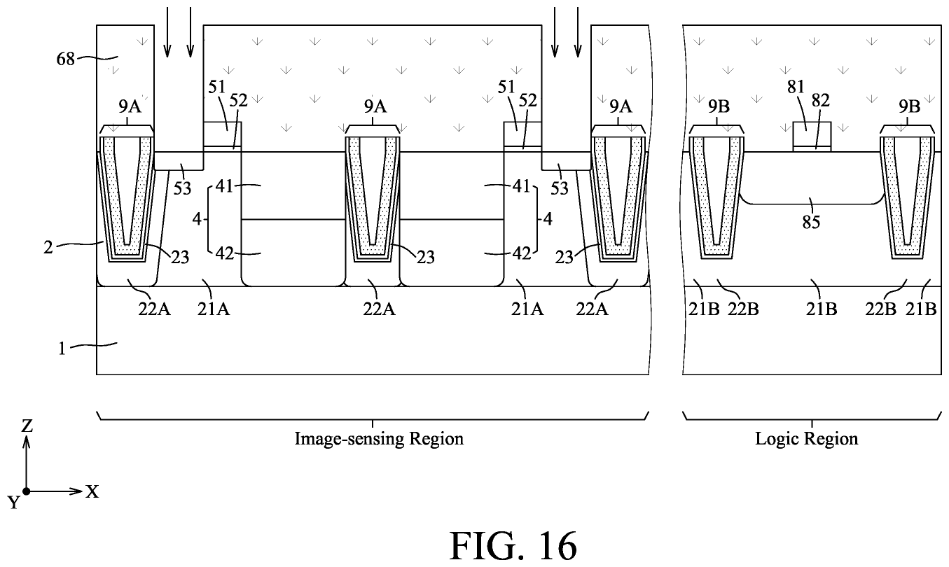

Referring to FIG. 3 and the example illustrated in FIG. 16, the method 6 proceeds to step S13, where the floating diffusion portions 53 are respectively in the first epitaxial regions 21A such that each of the floating diffusion portions 53 and a corresponding one of the photo-detecting portions 4 are respectively located at two opposite sides of a corresponding one of the transfer gates 51. FIG. 16 is a schematic sectional view similar to FIG. 15, but illustrating the structure after step S13.

In some embodiments, formation of the floating diffusion portions 53 may be performed in a manner similar to the second isolation implantation process in step S09, but process parameters (e.g., energy, dosage of impurities, species of impurities, etc.) of an implantation process for forming the floating diffusion portions 53 are adjusted so that the floating diffusion portions 53 may be formed at a desired depth and may have a desired doping concentration. In some embodiments, a patterned photoresist layer 68 used in step S13 is formed to expose predetermined portions of the patterned epitaxial layer 2 that are respectively designed for forming the floating diffusion portions 53 therein. In some embodiments, at the image-sensing region, the upper surfaces of the transfer gates 51 and the preformed trench isolations 9A are covered by the patterned photoresist layer 68.

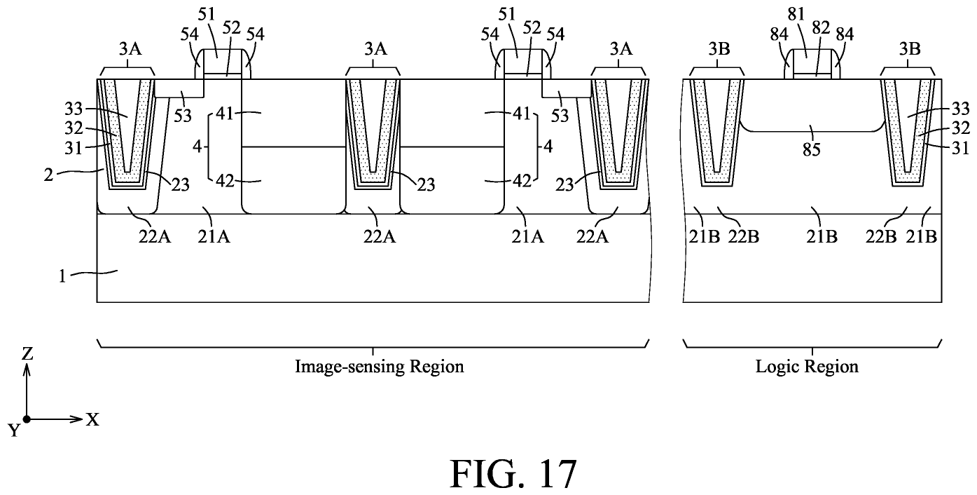

Referring to FIG. 3 and the example illustrated in FIG. 17, the method 6 proceeds to step S14, where the transfer gate spacers 54 and the logic gate spacers 84 are formed. FIG. 17 is a schematic sectional view similar to FIG. 16, but illustrating the structure after step S14.

In some embodiments, formation of the transfer gate spacers 54 and the logic gate spacers 84 may include (i) forming a spacer layer (not shown) for forming the elements 54 and 84 on the structure obtained after step S13 by a suitable deposition process such as CVD, and (ii) removing excess portions of the spacer layer to expose the upper surfaces of the transfer gates 51, the logic gates 81 and the patterned epitaxial layer 2 by a suitable etching process (e.g., anisotropic etching process), thereby obtaining the transfer gate spacers 54 and the logic gate spacers 84.

In some embodiments, the upper portion 902 of each of the preformed trench isolations 9A, 9B (see FIG. 14) may be further etched in step S14. In some embodiments, as shown in FIG. 17, for each of the preformed trench isolations 9A, 9B, the upper portion 902 is etched away after step S14, and the remaining lower portion 901 (see FIG. 14) serves as a corresponding one of the trench isolations 3A, 3B.

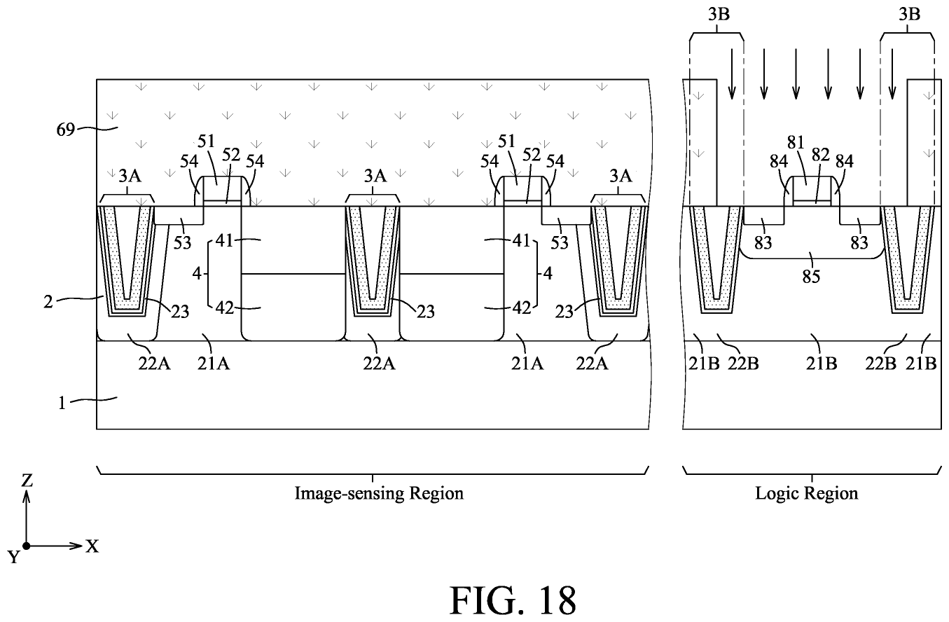

Referring to FIG. 3 and the example illustrated in FIG. 18, the method 6 proceeds to step S15, where the two source/drain portions 83 are formed in the middle second epitaxial region 21B, and are respectively located at two opposite sides of the logic gate 81. FIG. 18 is a schematic sectional view similar to FIG. 17, but illustrating the structure after step S15. After step S15, the semiconductor structure 100 shown in FIG. 1 is obtained.

In some embodiments, formation of the two source/drain portions 83 may be performed in a manner similar to formation of the floating diffusion portions 53 in step S13, but process parameters (e.g., energy, dosage of impurities, species of impurities, etc.) of an implantation process for forming the two source/drain portions 83 are adjusted so that the two source/drain portions 83 may be formed at a desired depth and may have a desired doping concentration. In some embodiments, a patterned photoresist layer 69 used in step S15 is formed to expose the middle second epitaxial region 21B.

In some embodiments, some steps in the method 6 may be modified, replaced, or eliminated without departure from the spirit and scope of the present disclosure.

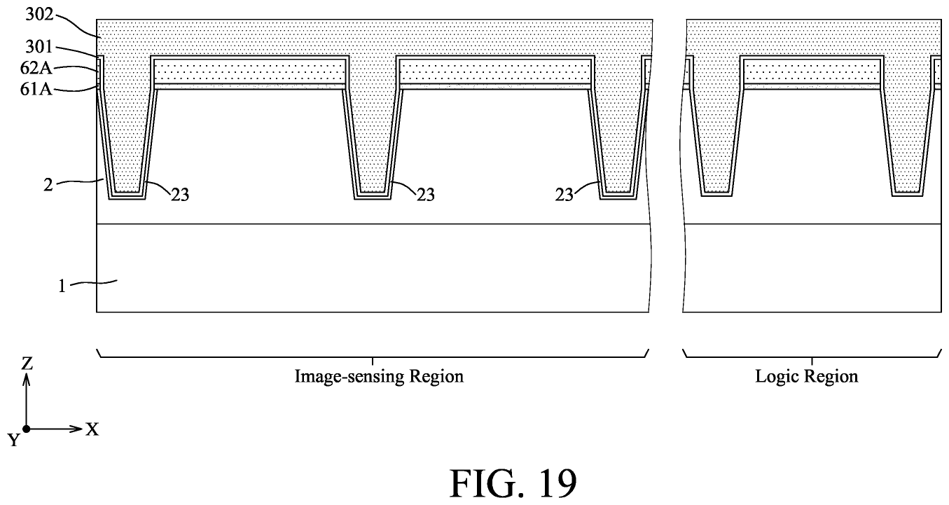

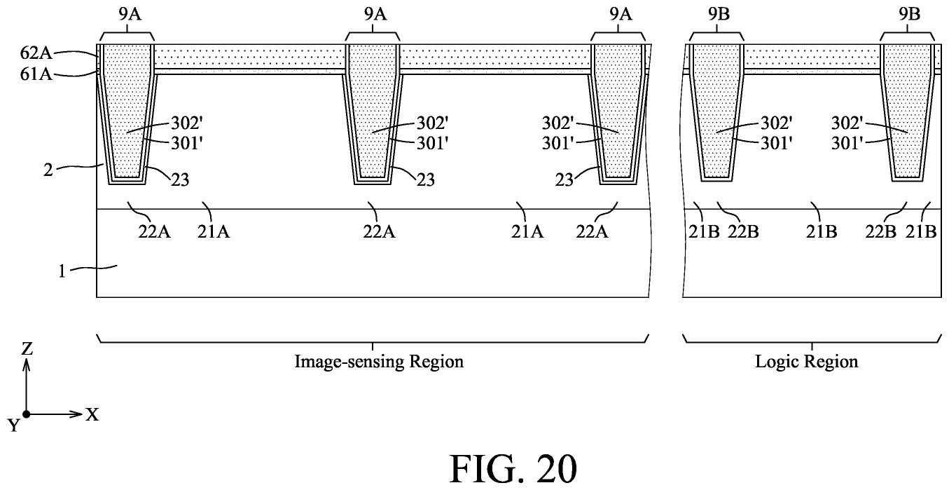

For example, in some embodiments, forming the semiconductor structure 200 shown in FIG. 2, step S06 in the method 6 may be omitted. Hence, in step S05, as shown in FIG. 19, the second film 302 is formed on the first film 301 to fill the trenches 30A, 30B (see FIG. 7A), and in step S07, as shown in FIG. 20, excess portions of the first film 301 and the second film 302 above the patterned polish stop layer 62A are removed. Each of the preformed isolation trenches 9A, 9B shown in FIG. 20 includes a portion of the patterned first film 301′ and a portion of the patterned second film 302′.

In some other embodiments, the semiconductor structure 100, 200 may be formed with the interconnect structure (not shown) as described above by a dual damascene process, a single damascene process, or other suitable back-end-of-line (BEOL) techniques.

In some embodiments, steps S12 to step 15 may be performed, for example, but not limited to, based on the sequence shown in FIG. 3. In some embodiments, step S12 (formation of the photo-detecting portions 4) may be performed before or after step S13 (formation of the floating diffusion portions 53). In some embodiments, each of step S12 and step S13 may be performed after step S14 (formation of the transfer gate spacers 54 and the logic gate spacers 84). In some embodiments, step S15 (formation of the source/drain portions 83) may be performed before step S14 and after step S11 (formation of the logic gate 81).

In summary, the trench isolation having configuration as described in the present disclosure may serve as a light reflector, and prevents a light incident to one of the pixel units from entering an adjacent one of the pixel units. Therefore, the pixel units (i.e., image sensors) of the present disclosure may be provided with enhanced quantum efficiency due to reduced loss of light. Furthermore, through selection of the precursor gas mixture for forming the trench isolation, a number of the dangling silicon bonds in the pixel units may be significantly reduced, thereby reducing dark current generated in the absence of light. It is worth noting that the trench isolation of the present disclosure at the image-sensing region can also be used to isolate two adjacent ones of the transistors at the logic region without adversely affecting the device performance of the transistors.

In accordance with some embodiments of the present disclosure, a semiconductor structure includes: an epitaxial layer; photo-detecting portions disposed in the epitaxial layer and spaced apart from each other, each of the photo-detecting portions including a p-n junction; and trench isolations disposed in the epitaxial layer, each of the trench isolations being disposed to separate two adjacent ones of the photo-detecting portions from each other. Each of the trench isolations includes a first dielectric layer having a first refractive index and a first thickness, and a second dielectric layer having a second refractive index that is different from the first refractive index, and a second thickness that is different from the first thickness. The first dielectric layer and the second dielectric layer are arranged to prevent a light incident to one of the photo-detecting portions from entering an adjacent one of the photo-detecting portions.

In accordance with some embodiments of the present disclosure, in each of the trench isolations, the first dielectric layer is disposed to separate the second dielectric layer from two adjacent ones of the photo-detecting portions, and a nitrogen concentration of the second dielectric layer is greater than a nitrogen concentration of the first dielectric layer.

In accordance with some embodiments of the present disclosure, the second refractive index is not less than 1.3 times the first refractive index.

In accordance with some embodiments of the present disclosure, a transmittance of the second dielectric layer is less than a transmittance of the first dielectric layer.

In accordance with some embodiments of the present disclosure, the first dielectric layer includes silicon oxide, the second dielectric layer includes silicon oxynitride. Each of the trench isolations further includes a dielectric filling portion which includes silicon oxide. The second dielectric layer is disposed between the first dielectric layer and the dielectric filling portion.

In accordance with some embodiments of the present disclosure, the second thickness is not less than 3.5 times the first thickness.

In accordance with some embodiments of the present disclosure, a method for manufacturing a semiconductor structure includes: patterning an epitaxial layer to form a patterned epitaxial layer; forming a trench isolation in the patterned epitaxial layer such that the trench isolation is located between two epitaxial regions of the patterned epitaxial layer, the trench isolation including a first dielectric layer and a second dielectric layer, a thickness and a refractive index of the first dielectric layer being different from a thickness and a refractive index of the second dielectric layer, respectively; forming two transfer gates respectively on the two epitaxial regions; forming two floating diffusion portions respectively in the two epitaxial regions; and forming two photo-detecting portions respectively in the two epitaxial regions such that a light incident to one of the two photo-detecting portions is prevented from entering another one of the two photo-detecting portions through the trench isolation, and such that each of the two photo-detecting portions and a corresponding one of the two floating diffusion portions are respectively located at two opposite sides of a corresponding one of the two transfer gates.

In accordance with some embodiments of the present disclosure, the first dielectric layer is formed to separate the second dielectric layer from the two epitaxial regions, a nitrogen concentration of the second dielectric layer is greater than a nitrogen concentration of the first dielectric layer, the thickness of the first dielectric layer is greater than 50 Å, and the thickness of the second dielectric layer is greater than the thickness of the first dielectric layer.

In accordance with some embodiments of the present disclosure, the epitaxial layer is patterned to form a trench having an inner surface connected to an upper surface of the patterned epitaxial layer. Formation of the trench isolation includes forming a first film on the patterned epitaxial layer to cover the inner surface of the trench, forming a second film on the first film to fill the trench, and removing excess portions of the first film and the second film to expose the upper surface of the patterned epitaxial layer, such that the first film and the second film are respectively formed into the first dielectric layer and the second dielectric layer.

In accordance with some embodiments of the present disclosure, the second film has a refractive index that is not less than 1.3 times a refractive index of the first film.

In accordance with some embodiments of the present disclosure, the epitaxial layer is made of crystalline silicon, the first film is made of silicon oxide, and the second film is made of silicon oxynitride.

In accordance with some embodiments of the present disclosure, during patterning the epitaxial layer, dangling silicon bonds are formed at the inner surface of the trench, and during formation of the second film, hydrogen atoms are generated to react with the dangling silicon bonds.

In accordance with some embodiments of the present disclosure, each of the two photo-detecting portions is disposed on a substrate and includes a first-type doped region and a second-type doped region which is disposed between the first-type doped region and the substrate. The first-type doped region has a conductivity type opposite to a conductivity type of the second-type doped region. Each of the two floating diffusion portions has a conductivity type that is the same as the conductivity type of the second-type doped region.

In accordance with some embodiments of the present disclosure, the patterned epitaxial layer further includes an underlying region disposed beneath the trench isolation and above the substrate. The method further includes introducing impurities into the underlying region such that the underlying region has a conductivity type that is opposite to the conductivity type of the second-type doped region, so as to isolate the second-type doped region of one of the two photo-detecting portions from the second-type doped region of another one of the two photo-detecting portions.

In accordance with some embodiments of the present disclosure, a method for manufacturing a semiconductor structure includes: patterning an epitaxial layer to form a patterned epitaxial layer; forming a trench isolation in the patterned epitaxial layer such that the trench isolation is located between two epitaxial regions of the patterned epitaxial layer, the trench isolation including a first dielectric layer, a dielectric filling portion, and a second dielectric layer formed between the first dielectric layer and the dielectric filling portion, a refractive index of the first dielectric layer being different from a refractive index of the second dielectric layer, each of the first dielectric layer and the dielectric filling portion including silicon oxide; forming two transfer gates respectively on the two epitaxial regions; forming two floating diffusion portions respectively in the two epitaxial regions; and forming two photo-detecting portions respectively in the two epitaxial regions such that a light incident to one of the two photo-detecting portions is prevented from entering another one of the two photo-detecting portions through the trench isolation, and such that each of the two photo-detecting portions and a corresponding one of the two floating diffusion portions are respectively located at two opposite sides of a corresponding one of the transfer gates.

In accordance with some embodiments of the present disclosure, the epitaxial layer is patterned to form a trench having an inner surface connected to an upper surface of the patterned epitaxial layer. Formation of the trench isolation includes forming a first film on the patterned epitaxial layer to cover the inner surface of the trench, forming a second film and a filling material on the first film to fill the trench, and removing excess portions of the first film, the second film and the filling material to expose the upper surface of the patterned epitaxial layer, such that the first film, the second film and the filling material are respectively formed into the first dielectric layer, the second dielectric layer and the dielectric filling portion.

In accordance with some embodiments of the present disclosure, the second film has a refractive index that is not less than 1.3 times a refractive index of the first film.

In accordance with some embodiments of the present disclosure, the epitaxial layer is made of crystalline silicon, the first film is made of silicon oxide, the second film is made of silicon oxynitride, and the filling material is made of silicon oxide.

In accordance with some embodiments of the present disclosure, during patterning the epitaxial layer, dangling silicon bonds are formed at the inner surface of the trench, and during formation of the second film, hydrogen atoms are generated to react with the dangling silicon bonds.

In accordance with some embodiments of the present disclosure, each of the two photo-detecting portions includes a p-n junction or pin junction for converting an incident light into electrical signals.

In accordance with some embodiments of the present disclosure, a method for forming a semiconductor structure includes: forming photo-detecting portions in an epitaxial layer, the photo-detecting portions being spaced apart from each other, each of the photo-detecting portions having a p-n junction; and forming trench isolations in the epitaxial layer, each of the trench isolations being disposed to separate two adjacent ones of the photo-detecting portions from each other, each of the trench isolations including a first dielectric layer having a first refractive index and a first thickness, and a second dielectric layer having a second refractive index that is different from the first refractive index, and a second thickness that is different from the first thickness, the first dielectric layer and the second dielectric layer being arranged to prevent a light incident to one of the photo-detecting portions from entering an adjacent one of the photo-detecting portions.

In accordance with some embodiments of the present disclosure, in each of the trench isolations, the first dielectric layer is disposed to separate the second dielectric layer from two adjacent ones of the photo-detecting portions, and a nitrogen concentration of the second dielectric layer is greater than a nitrogen concentration of the first dielectric layer.

In accordance with some embodiments of the present disclosure, the second refractive index is not less than 1.3 times the first refractive index.

In accordance with some embodiments of the present disclosure, the first dielectric layer includes silicon oxide, the second dielectric layer includes silicon oxynitride, and each of the trench isolations further includes a dielectric filling portion which includes silicon oxide. The second dielectric layer is disposed between the first dielectric layer and the dielectric filling portion.

In accordance with some embodiments of the present disclosure, the second thickness is not less than 3.5 times the first thickness.

In accordance with some embodiments of the present disclosure, the method further includes: forming transfer gates which are disposed on the epitaxial layer; forming transfer gate dielectrics to respectively separate the transfer gates from the epitaxial layer; and forming floating diffusion portions in the epitaxial layer, such that each of the photo-detecting portions and a corresponding one of the floating diffusion portions are respectively located at two opposite sides of a corresponding one of the transfer gates.

The foregoing outlines features of several embodiments so that those skilled in the art may better understand the aspects of the present disclosure. Those skilled in the art should appreciate that they may readily use the present disclosure as a basis for designing or modifying other processes or structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor structure, comprising:
an epitaxial layer;
photo-detecting portions disposed in the epitaxial layer and spaced apart from each other, each of the photo-detecting portions including a p-n junction; and
trench isolations disposed in the epitaxial layer, each of the trench isolations being disposed to separate two adjacent ones of the photo-detecting portions from each other, each of the trench isolations including
a first dielectric layer having a first refractive index and a first thickness, and
a second dielectric layer having a second refractive index that is different from the first refractive index, and a second thickness that is different from the first thickness, the first dielectric layer and the second dielectric layer being arranged to prevent a light incident to one of the photo-detecting portions from entering an adjacent one of the photo-detecting portions.

2. The semiconductor structure as claimed in claim 1, wherein in each of the trench isolations, the first dielectric layer is disposed to separate the second dielectric layer from two adjacent ones of the photo-detecting portions, and a nitrogen concentration of the second dielectric layer is greater than a nitrogen concentration of the first dielectric layer.

3. The semiconductor structure as claimed in claim 2, wherein the second refractive index is not less than 1.3 times the first refractive index.

4. The semiconductor structure as claimed in claim 2, wherein a transmittance of the second dielectric layer is less than a transmittance of the first dielectric layer.

5. The semiconductor structure as claimed in claim 2, wherein
the first dielectric layer includes silicon oxide,
the second dielectric layer includes silicon oxynitride, and
each of the trench isolations further includes a dielectric filling portion which includes silicon oxide, the second dielectric layer being disposed between the first dielectric layer and the dielectric filling portion.

6. The semiconductor structure as claimed in claim 5, wherein the second thickness is not less than 3.5 times the first thickness.

7. A method for manufacturing a semiconductor structure, comprising:
patterning an epitaxial layer to form a patterned epitaxial layer;
forming a trench isolation in the patterned epitaxial layer such that the trench isolation is located between two epitaxial regions of the patterned epitaxial layer, the trench isolation including a first dielectric layer and a second dielectric layer, a thickness and a refractive index of the first dielectric layer being different from a thickness and a refractive index of the second dielectric layer, respectively;
forming two transfer gates respectively on the two epitaxial regions;
forming two floating diffusion portions respectively in the two epitaxial regions; and
forming two photo-detecting portions respectively in the two epitaxial regions such that a light incident to one of the two photo-detecting portions is prevented from entering another one of the two photo-detecting portions through the trench isolation, and such that each of the two photo-detecting portions and a corresponding one of the two floating diffusion portions are respectively located at two opposite sides of a corresponding one of the two transfer gates.

8. The method as claimed in claim 7, wherein
the first dielectric layer is formed to separate the second dielectric layer from the two epitaxial regions,
a nitrogen concentration of the second dielectric layer is greater than a nitrogen concentration of the first dielectric layer,
the thickness of the first dielectric layer is greater than 50 Å, and
the thickness of the second dielectric layer is greater than the thickness of the first dielectric layer.

9. The method as claimed in claim 7, wherein
the epitaxial layer is patterned to form a trench having an inner surface connected to an upper surface of the patterned epitaxial layer, and
formation of the trench isolation includes
forming a first film on the patterned epitaxial layer to cover the inner surface of the trench,
forming a second film on the first film to fill the trench, and
removing excess portions of the first film and the second film to expose the upper surface of the patterned epitaxial layer, such that the first film and the second film are respectively formed into the first dielectric layer and the second dielectric layer.

10. The method as claimed in claim 9, wherein the second film has a refractive index that is not less than 1.3 times a refractive index of the first film.

11. The method as claimed in claim 9, wherein
the epitaxial layer is made of crystalline silicon,
the first film is made of silicon oxide, and
the second film is made of silicon oxynitride.

12. The method as claimed in claim 11, wherein
during patterning the epitaxial layer, dangling silicon bonds are formed at the inner surface of the trench, and
during formation of the second film, hydrogen atoms are generated to react with the dangling silicon bonds.

13. The method as claimed in claim 7, wherein
each of the two photo-detecting portions is disposed on a substrate and includes a first-type doped region and a second-type doped region which is disposed between the first-type doped region and the substrate, the first-type doped region having a conductivity type opposite to a conductivity type of the second-type doped region, and
each of the two floating diffusion portions has a conductivity type that is the same as the conductivity type of the second-type doped region.

14. The method as claimed in claim 13, wherein
the patterned epitaxial layer further includes an underlying region disposed beneath the trench isolation and above the substrate, and
the method further comprises introducing impurities into the underlying region such that the underlying region has a conductivity type that is opposite to the conductivity type of the second-type doped region, so as to isolate the second-type doped region of one of the two photo-detecting portions from the second-type doped region of another one of the two photo-detecting portions.

15. A method for manufacturing a semiconductor structure, comprising:
patterning an epitaxial layer to form a patterned epitaxial layer;
forming a trench isolation in the patterned epitaxial layer such that the trench isolation is located between two epitaxial regions of the patterned epitaxial layer, the trench isolation including a first dielectric layer, a dielectric filling portion, and a second dielectric layer formed between the first dielectric layer and the dielectric filling portion, a refractive index of the first dielectric layer being different from a refractive index of the second dielectric layer, each of the first dielectric layer and the dielectric filling portion including silicon oxide;
forming two transfer gates respectively on the two epitaxial regions;
forming two floating diffusion portions respectively in the two epitaxial regions; and
forming two photo-detecting portions respectively in the two epitaxial regions such that a light incident to one of the two photo-detecting portions is prevented from entering another one of the two photo-detecting portions through the trench isolation, and such that each of the two photo-detecting portions and a corresponding one of the two floating diffusion portions are respectively located at two opposite sides of a corresponding one of the transfer gates.

16. The method as claimed in claim 15, wherein
the epitaxial layer is patterned to form a trench having an inner surface connected to an upper surface of the patterned epitaxial layer, and
formation of the trench isolation includes
forming a first film on the patterned epitaxial layer to cover the inner surface of the trench,
forming a second film and a filling material on the first film to fill the trench, and
removing excess portions of the first film, the second film and the filling material to expose the upper surface of the patterned epitaxial layer, such that the first film, the second film and the filling material are respectively formed into the first dielectric layer, the second dielectric layer and the dielectric filling portion.

17. The method as claimed in claim 16, wherein the second film has a refractive index that is not less than 1.3 times a refractive index of the first film.

18. The method as claimed in claim 16, wherein
the epitaxial layer is made of crystalline silicon,
the first film is made of silicon oxide,
the second film is made of silicon oxynitride, and
the filling material is made of silicon oxide.

19. The method as claimed in claim 16, wherein
during patterning the epitaxial layer, dangling silicon bonds are formed at the inner surface of the trench, and
during formation of the second film, hydrogen atoms are generated to react with the dangling silicon bonds.

20. The method as claimed in claim 15, wherein each of the two photo-detecting portions includes a p-n junction or pin junction for converting an incident light into electrical signals.
